(19) United States
(12) Patent Application Publication
(10) Pub. No.: US 2008/0036552 A1
(43) Pub. Date: Feb. 14, 2008

(54) Method and Circuit Arrangement for the Production of an Output Signal of a Predefined Average Size From a Relatively Larger Input Signal by Pulse-Width Modulated Connection of Said Input Signal

(75) Inventors: Uli Joos, Nonnenhorn (DE); Josef Schnell, Wasserburg (DE)

Correspondence Address: CONTINENTAL TEVES, INC., ONE CONTINENTAL DRIVE, AUBURN HILLLS, MI, 48326-1581, US

(73) Assignee: Conti Temic Microelectronic GMBH

(21) Appl. No.: 11/660,632

(22) PCT Filed: Jul. 14, 2005
(86) PCT No.: PCT/DE05/01243

§ 371 Date: Feb. 20, 2007

(30) Foreign Application Priority Data
Aug. 19, 2004 (DE) 10 2004 040 252.3

(51) Int. Cl. H03K 7/08; H03K 3/017

(52) U.S. Cl. 332/109; 327/175

(57) ABSTRACT

The invention introduces a method for the production of an output signal having a predefined average size from a relatively larger input signal by pulse-width modulated connection of the input signal, wherein the pulse-width modulation has a predefined number of discrete, adjustable pulse widths within a pulse width and each pulse width corresponds to a specific average output-signal size. A super frame consisting of at least two successive pulses is chosen in order to produce an output signal which has an average size and which does not correspond to one of the discretely adjustable pulse widths. At least two pulses inside the super frame have a different pulse width such that the average output signal size corresponds to the predefined size. As a result, it is possible to produce intermediate average size values which can not be represented by a pulse width, in addition to such average size values which can not be produced as a result of the switching delay of the pulse-width modulation controlled switching means in a pulse width.

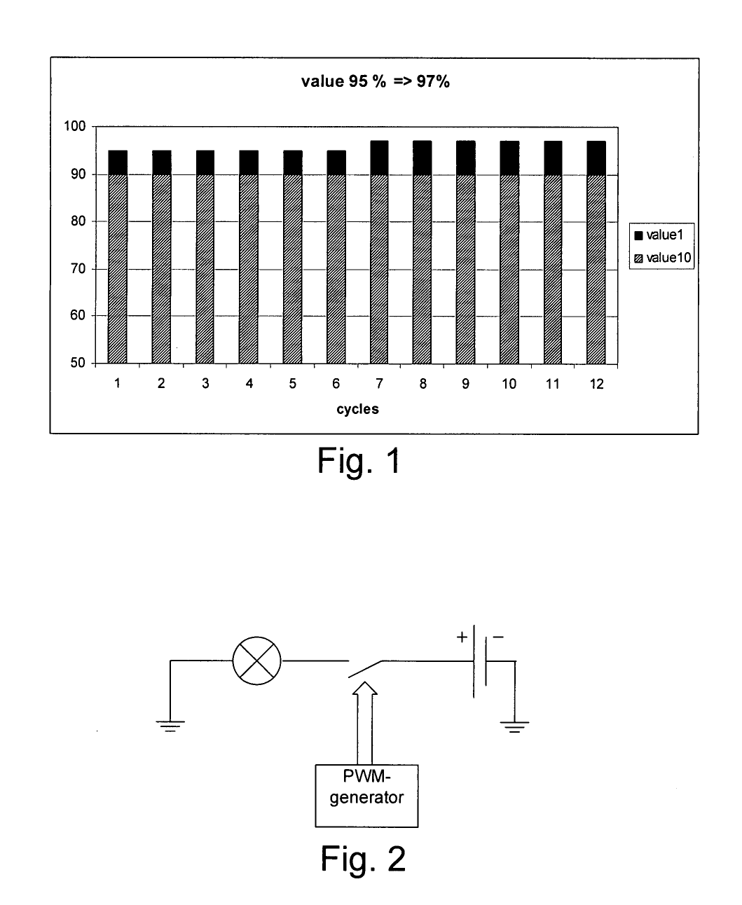

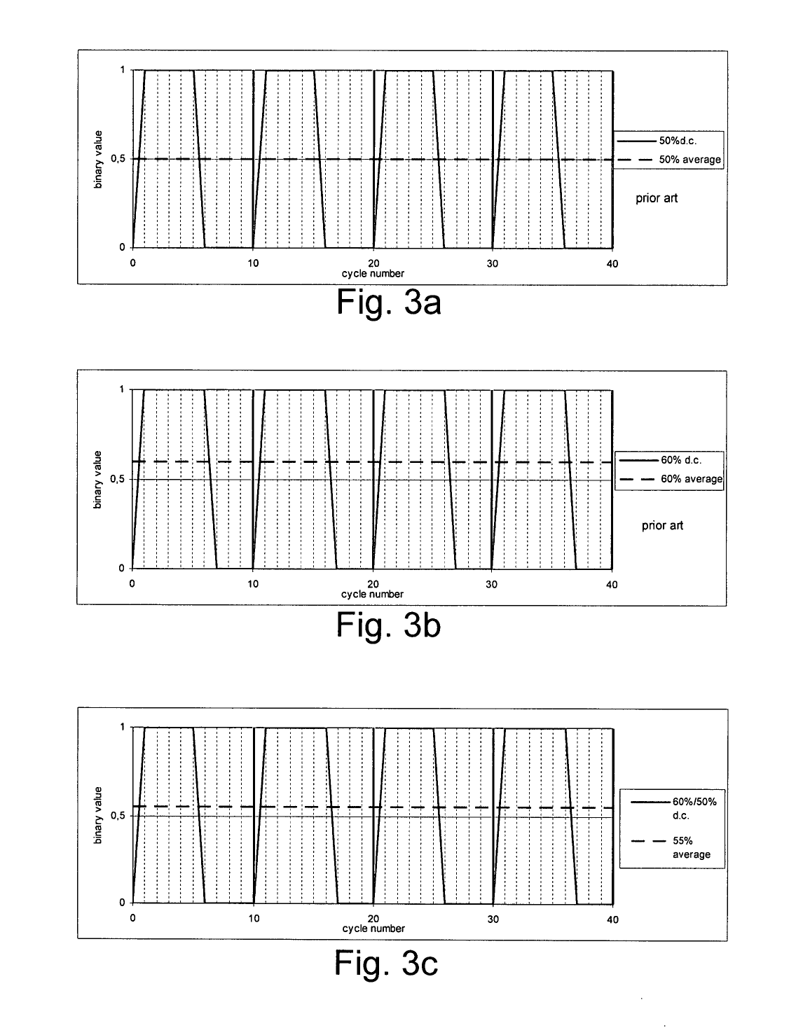

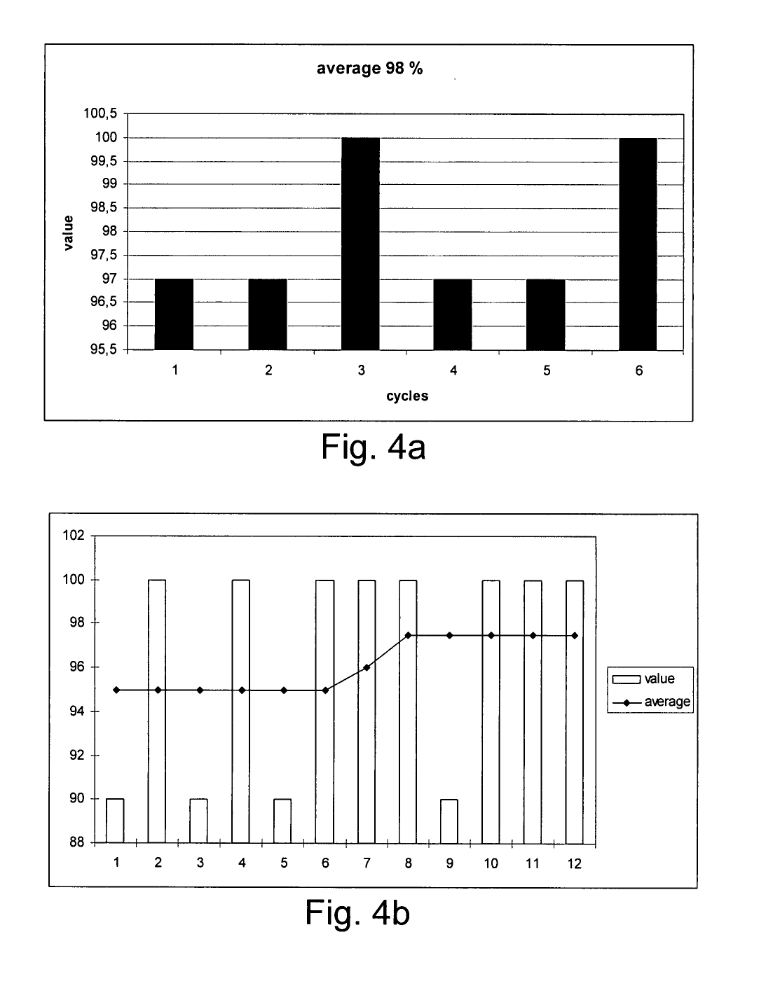

The invention relates to a method and to a circuit arrangement for the production of an output signal having a predefined average size from a relatively larger input signal by pulse-width modulated connection of the input signal.

The control of many electrical loads, for example in the motor vehicle (e.g. lamps, heating coils, . . . ) is effected by means of pulse width modulation (PWM), wherein the power released to the load can be regulated or controlled in the region 0 . . . 100%. Thus, for example, the average output voltage or output power is controlled or regulated by pulse-width modulation. If for the downstream consumer an equi-signal level, i.e. for example a direct voltage is required, corresponding smoothing filters can be connected between the PWM-regulating step and the consumer.

In vehicle control devices PWM signals are usually produced via timer modules integrated into the μcontroller, the resolution of the timer having to be limited by different parameters to reasonable values (e.g. 8 bit). Hence, the resolution of the PWM is limited by the discrete representable pulse widths, in particular by the digital resolution of the used counters. The smallest step in the change of control thus results by Pₘₐₓ/2ⁿ, smaller steps cannot be represented.

A further limiting factor of pulse-width modulated signals are extreme pulse widths (near 0% or 100%, resp.), in particular if the switching delays and build-up restrictions usual for EMC reasons are integrated into the power stage. In this case pulse widths smaller than the total delay cannot be represented or only at considerable expenditure. Partially, in addition the useable region of the modulation is restricted, as pulse widths smaller than the switching delay of the power stage usually cannot be represented.

It is, therefore, the object of the invention to indicate a method and a circuit arrangement, in which the resolution is improved and/or average sizes, which could not be adjusted so far, can be achieved. This object is solved by the features of the independent claims. Advantageous further embodiments can be taken from the sub-claims.

If, in general, the resolution with a PWM-control was intended to be increased, counters with a correspondingly higher resolution and a faster pulsing would be used for this purpose, what, however, clearly increases the expenditure.

The invention is based on the fact that several modulations can be super-imposed for achieving a more refined grading. For this purpose a super frame consisting of at least two successive pulses is chosen, wherein at least two pulses inside the super frame have a different pulse width such that the average output signal size corresponds to the predefined size.

If one starts for example from a 3-bit-resolution and thus 8 different pulse widths, by a super frame of two pulses each and use of respectively adjacent pulse widths the resolution of the average size to be adjusted can virtually be doubled, without having to actually increase the bit resolution and the pulsing. If one increases the number of pulses inside the super frame, still more refined resolutions can be represented. A practical limit in this case, is only the admissible length of the super frame, which is different for each application, and thus of the time period, within which the average size must be achieved. Thus, output signals having an average size can be produced, which correspond to an intermediate value between the discretely predefined pulse widths. Preferably, the super frame is repeated several times.

A circuit arrangement for the production of an output signal having a predefined average size from a relatively larger input signal by pulse-width modulated connection of the input signal to the output thus requires simply a correspondingly controllable switching means as well as a control device for executing a method. The control device must control the pulse widths inside a super frame in correspondence to the average size to be adjusted.

Here, it is possible that with the circuit arrangement in a rough adjusting mode the average size of the output signal is predefined at equidistant steps as a pulse width within a pulse width as a digital value of a predefined first bit number discretely with a frequency predefined by a pulse generator. In a fine adjusting mode the average size of the output signal is predefined as a digital value with a second, with relation to the first higher bit number more refined resolution, wherein for each digital value in the fine adjusting mode the number of the pulses inside a super frame and their pulse widths are stored in a table and by a corresponding adjustment of the pulse width of the pulses inside the super frame with the same pulse frequency of the pulse generator the output signal can be produced in correspondence to the second bit number of predefined average size.

As a rule, the pulse width is predefined at equidistant steps along the total pulse width. The switching means, which is to be controlled pulse-width modulated, partially has a switching flank width which is larger than at least one equidistant step of this type, so that pulse width within a lower limit region and above an upper limit region cannot be produced. The method can be used also for this purpose. For the production of output signals having an average size, which corresponds to a pulse width within the lower limit region, in a super frame a corresponding number of pulses with a pulse width zero percent and with a pulse width lying above the lower limit region can be used. For the production of output signals having an average size, which corresponds to a pulse width within the upper limit region, in a super frame a corresponding number of pulses with a pulse width hundred percent and with a pulse width lying below the upper limit region can be used.

The following table demonstrates the facts for a modulation with 100 steps, wherein the resolution 1/100 and the minimum pulse width 3 (or 97, resp.) caused by switching delays corresponds to:

| | Target value | Basic- | Super- |
|---|---|---|---|
| No. | [%] | modulation [%] | modulation [%] |
| 1 | 95 | 95 | — |
| 2 | 95.5 | 1 pulse 95 | 1 pulse 96 |
| 3 | 96 | 96 | — |
| 4 | 97 | 97 | — |
| 5 | 98 | 2 pulses 97 | 1 pulse 100 |
| 6 | 99 | 1 pulse 97 | 2 pulses 100 |
| 7 | 100 | 100 | — |

The steps 1,3,4,7 represent the basic modulation and can be simply represented by the modulator.

Step 2, in contrast, is an intermediate value and cannot be represented by the usual method. For the production of the value a further modulation must be superimposed. It consists of an alternating control of the adjacent PWM-values 95 and 96. The resulting value results from the average value of the used surfaces and thus to (95+96)12=95,5.

The steps 6 and 7 represent values, which cannot be represented due to the switching delay. But also these values can be produced by superimposition of potential values (here 97 and 100):

| | |
|---|---|
| Step 6: | (2 × 97 + 1 × 100)/3 = 98 |
| Step 7: | (1 × 97 + 2 × 100)/3 = 99 |

This method and/or a corresponding circuit arrangement can be used for example for the production of an electrical output voltage of a predefined average size for an electrical load element, in particular for one or more parallel connected light bulbs, or are suitable for use in a closed loop for controlling the average electrical power at an electrical load element.

When producing the intermediate values further, low-frequent portions are superimposed to the modulation frequency, which, however, have only a small modulation amplitude caused by the small difference between the pulse widths inside a super frame and thus can be mostly be tolerated.

These super modulation frequencies are advantageously executed with a subharmonics of the modulation frequency, but, however, also independent frequencies can be used.

1) a method for the production of an output signal having a predefined average size from a relatively larger input signal by pulse-width modulated connection of the input signal,
a) wherein the pulse-width modulation has a predefined number of discrete, adjustable pulse widths within a pulse width and each pulse width corresponds to a specific average output-signal size,
characterized in that
b) a super frame consisting of at least two successive pulses is chosen in order to produce an output signal which has an average size and which does not correspond to one of the discretely adjustable pulse widths and at least two pulses inside the super frame have a different pulse width such that the average output signal size corresponds to the predefined size.

2) A method according to claim 1, characterized in that the super frame is repeated at least once.

3) Use of the method according to one of the preceding claims for the production of an output signal having an average size, which corresponds to an intermediate value between the discretely predefined pulse widths.

4) A circuit arrangement for the production of an output signal having a predefined average size from a relatively larger input signal by pulse-width modulated connection of the input signal to the output via a controllable switching means with a control device for executing a method according to one of the preceding claims.

5) A circuit arrangement according to one of the preceding claims, wherein
a) in a rough adjusting mode the average size of the output signal is predefined at equidistant steps as a pulse width within a pulse width as a digital value of a predefined first bit number discretely with a frequency predefined by a pulse generator and
b) in a fine adjusting mode the average size of the output signal is predefined as a digital value with a second, with relation to the first higher bit number more refined resolution, wherein for each digital value in the fine adjusting mode the number of the pulses inside a super frame and their pulse widths are stored in a table and by a corresponding adjustment of the pulse width the pulses inside the super frame with the same pulse frequency of the pulse generator the output signal can be produced corresponding to the second bit number of predefined average size.

6) A circuit arrangement according to one of the preceding claims,
a) wherein the pulse width is predefined at equidistant steps along the entire pulse width and
b) the switching means, which is to be controlled pulse-width modulated, has a switching flank width which is larger than at least one equidistant step of this type, so that the pulse widths within a lower limit region and above an upper limit region can not be produced and
c) for the production of output signals having an average size, which corresponds to a pulse width within the lower limit region, in a super frame a corresponding number of pulses with a pulse width zero percent and with a pulse width lying above the lower limit region can be used and/or
d) for the production of output signals having an average size, which corresponds to a pulse width within the upper limit region, in a super frame a corresponding number of pulses with a pulse width hundred percent and with a pulse width lying below the upper limit region can be used.

7) Use of a method and/or of a circuit arrangement according to one of the preceding claims for the production of an electrical output voltage of a predefined average size for an electrical load element, in particular for a light bulb.

8) Use of a method and/or of a circuit arrangement according to one of the preceding claims in a closed loop for controlling the average electrical power at an electrical load element.
